(19) United States
(12) Patent Application Publication
(10) Pub. No.: US 2025/0391448 A1
(43) Pub. Date: Dec. 25, 2025

(54) MULTISTAGE WAKE UP CIRCUIT

(71) Applicant: SILVACO Inc., Santa Clara, CA (US)

(72) Inventor: Jean-Baptiste Dumaine, Grenoble (FR)

(73) Assignee: SILVACO Inc., Santa Clara, CA (US)

(21) Appl. No.: 18/878,548

(22) PCT Filed: Jun. 21, 2023
(86) PCT No.: PCT/US2023/025889

§ 371 Date: Dec. 23, 2024

Related U.S. Application Data
(60) Provisional application No. 63/354,583, filed on Jun. 22, 2022.

(51) Int. Cl. G11C 5/14; H02J 9/00; H03K 19/00

(52) U.S. Cl. CPC G11C 5/148; G11C 5/147; H02J 9/005; H03K 19/0016

(57) ABSTRACT

Technologies and implementations for a wake-up circuit. The wake-up circuit may be configured to reduce a peak value of current draw during waking up of an electronic device. The reduction of the peak value of current draw facilitates a reduction of electrical burden on various components of related circuit. Managing wake-up of circuits may include managing wake up of memory.

### CROSS-REFERENCE TO RELATED APPLICATIONS

This application claims benefit of priority to U.S. Provisional Patent Application Ser. No. 63/354,583, filed Jun. 22, 2022, titled MULTISTAGE WAKE UP CIRCUIT, which is incorporated herein by reference in its entirety for all purposes.

### BACKGROUND

Unless otherwise indicated herein, the approaches described in this section are not prior art to the claims in this application and are not admitted to be prior art by inclusion in this section.

Waking up memories, which may be in retention or deep-sleep mode, may face a compromise between wake-up speed and current draw. For example, a high current may reduce the wake-up speed but may cause an electrical burden on the circuit associated with the waking up of the memory. In order to facilitate a reduction of the electrical burden on the circuit, the wake-up speed may be slowed. However, slowing the wake-up speed may not be acceptable for a variety of reasons. Accordingly, a balance of electrical burden on the circuit and wake-up speed may be difficult.

All subject matter discussed in this section of this document is not necessarily prior art and may not be presumed to be prior art simply because it is presented in this section. Plus, any reference to any prior art in this description is not and should not be taken as an acknowledgement or any form of suggestion that such prior art forms parts of the common general knowledge in any art in any country. Along these lines, any recognition of problems in the prior art are discussed in this section or associated with such subject matter should not be treated as prior art, unless expressly stated to be prior art. Rather, the discussion of any subject matter in this section should be treated as part of the approach taken towards the particular problem by the inventor(s). This approach in and of itself may also be inventive. Accordingly, the foregoing summary is illustrative only and not intended to be in any way limiting. In addition to the illustrative aspects, embodiments, and features described above, further aspects, embodiments, and features will become apparent by reference to the drawings and the following detailed description.

### SUMMARY

Described herein are various illustrative devices, systems, and methods for managing wake up of circuits. Some example systems may include a control system for circuits associated with waking up memory. The example systems may include various power related circuits such as, but not limited to, a number of power switches. The power switches may be controlled by a control system such as, but not limited to, a ramp-up control system. In one example, the ramp-up control system may be configured as a multi-stage ramp-up control system. The multi-stage ramp-up control system may be configured to activate substantially all of the power switches substantially simultaneously.

As a result, the control system may be configured to facilitate focusing on modulating a level of a control signal of the power switches. The modulation of the level of the control signal of the power switches may help to flatten a current draw during power-up. In one example, the flattening of the current draw may be facilitated by controlling a current flux. Controlling the current flux may be an alternative to an approach of adding multiple delayed current fluxes.

The foregoing summary is illustrative only and not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

Subject matter is particularly pointed out and distinctly claimed in the concluding portion of the specification. The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 illustrates examples of some components, which may be utilized to describe the various embodiments as disclosed herein.

FIG. 2 illustrates a block diagram of a system for facilitating management of wake up of circuits in accordance with various embodiments.

FIG. 3 illustrates an operation flow of the various embodiments disclosed herein.

FIG. 4 illustrates a computer program product in accordance with various embodiments.

FIG. 5 illustrates examples of some components as to described with respect to various embodiments.

FIG. 6 illustrates examples of some output corresponding to various embodiments.

FIG. 7 illustrates an example computer device.

### DETAILED DESCRIPTION

The following description sets forth various examples along with specific details to provide a thorough understanding of claimed subject matter. It will be understood by those skilled in the art after review and understanding of the present disclosure, however, that claimed subject matter may be practiced without some or more of the specific details disclosed herein. Further, in some circumstances, well-known methods, procedures, systems, components and/or circuits have not been described in detail in order to avoid unnecessarily obscuring claimed subject matter.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

This disclosure is drawn, inter alia, to methods, apparatus, and systems system related to managing wake-up of circuits. Managing wake-up of circuits may include managing wake up of memory.

Memory wake-up circuits, which may be known as memory activation circuits, may be considered to be fundamental components used in electronic devices to facilitate management and control of various memory related operations. Memory wake-up circuits have a relatively important role in facilitating a transition between power saving modes and active modes, which may affect efficient memory utilization and optimal power consumption.

Memory wake-up circuits may facilitate addressing an increased demand for power efficient systems such as, but not limited to, portable devices (e.g., smart phones, tablets, laptops, portable PC, etc.) and various networked devices (e.g., IoT devices). As these devices become more sophisticated and feature rich, power conservation while reducing negative effects on performance may be of some concern. Accordingly, memory wake-up circuits may help to facilitate a variety of solutions to help conservation of power while reducing the negative effects on performance.

One example function of a memory wake-up circuit may be to manage the power state of memory devices (i.e., modules). For example, when a device such as, but not limited to, a memory, enters a low power or sleep mode, a memory wake-up circuit may facilitate placing the device (e.g., subsystem) in an idle state, which may consume minimal power. However, when the system needs to access or modify data stored in the memory, the wake-up circuit may be configured to activate the memory module, which may facilitate the memory device having the ability to respond to read or write requests from the processor or other devices.

Memory wake-up circuits may employ various methodologies to facilitate achievement of efficient power management. For example, a memory wake-up circuit may be configured to monitor system activity such as, but not limited to, processor commands, peripheral interactions, external stimuli (e.g., user input or sensor data), and so forth. By continuously monitoring these inputs, the wake-up circuit may be configured to determine when memory access may be requested, which may facilitate the reduction of unnecessary power consumption during idle periods.

In addition to managing power states, memory wake-up circuits may be configured to manage a wide variety of tasks. For example, a memory wake-up circuit may be configured to manage memory initialization during a system boot up, which may facilitate ensuring that the memory modules are properly configured and ready for use. In another example, a memory wake-up circuit may be configured to include error detection and correction mechanisms to maintain data integrity and reliability.

With advancement of technology, memory wake-up circuits may have evolved to meet the demands of an ever-increasing power processing and energy efficiency requirements. Wake-up circuits may be adapted to work with a wide variety of memory technologies such as, but not limited to, static random-access memory (SRAM), dynamic random-access memory (DRAM), emerging nonvolatile memory (NVM) technologies such as, but not limited to, phase change memory (PCM), resistive random-access memory (RRAM), or the like.

Wake-up circuits may be integral components, which may facilitate enablement of efficient power management and performance in modern electronic devices. A wake-up circuit's ability to seamlessly transition memory modules between power saving states and active states may facilitate an optimal operation and may contribute to overall functionality and battery life of various electronic devices.

Some approaches to waking up memory may include solutions configured to reduce a peak value of current draw during waking up of memory. Reducing the peak value of the current draw may help to facilitate reduction of electrical burden on various components of the related circuits. An example approach may be to cascade the wake-up of the memory by activating power switches sequentially. Activating the power switches sequentially may facilitate a flattening of the current draw through multiple delayed low current peaks. However, the cascade wake-up approach may be optimized towards a single PVT. For example, if the cascade wake-up approach is optimized for Fast corners, wake-up might be too slow for Slow corners. Additionally, if the cascade wake-up approach is optimized for Slow corner, in-rush current may be too high for Fast corners. If a compromise approach is utilized, the cascade wake-up approach may be the worst of both worlds. Accordingly, in various embodiments disclosed herein, approaches to reducing the peak value of the current draw may include approaches that may be configured to be self-regulated with regards to PVT corners. Self-regulated systems may automatically reduce the in-rush current when in Fast corners while not negatively affecting the Slow corners.

In various embodiments, approaches to reducing the peak value of the current draw may include reduction of electrical burden on on-board power regulators. For example, reducing the peak value of the current draw (i.e., flatten or make flatter the current), the on-board power regulators may be capable of following the current, which may facilitate in helping to reduce the burden on the power regulators. Additionally, reducing the peak value of the current draw may help to facilitate the power regulators driving the power without the need to adjust the size of the power regulators. For example, in order to counter act having large peak values of the current draw, a larger power regulator may be utilized, which may not be a desired solution.

In some embodiments, a wake-up speed and in-rush current may be modulated through a few strategically placed transistors. Strategically placed transistors may facilitate modulating the wake-up speed and in-rush current without duplicating delay paths to change the wake-up speed, which may be common for cascaded type approach for wake-up.

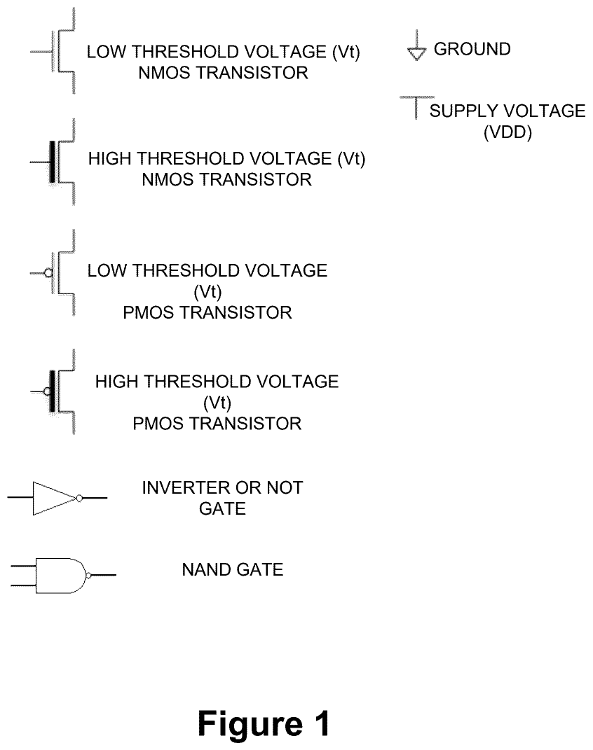

Turning now to FIG. 1, FIG. 1 illustrates examples of some components, which may be utilized to describe the various embodiments as disclosed herein. It should be appreciated that the example components are but just some examples, and accordingly, the claimed subject matter may include substitute components and/or similar components. The claimed subject matter is not limited in these respects.

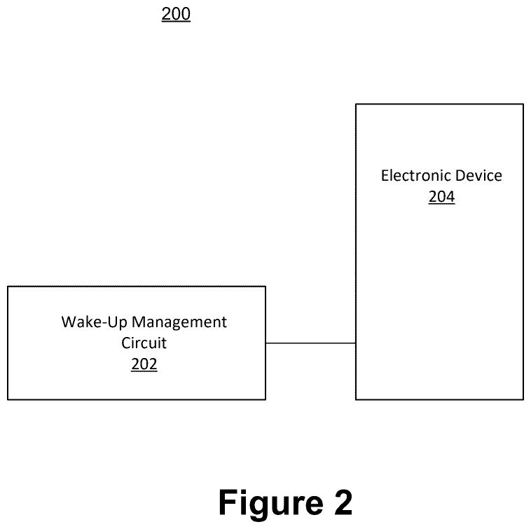

FIG. 2 illustrates a block diagram of a system for facilitating management of wake up of circuits in accordance with various embodiments. In FIG. 2, an integrated circuit system 200 may include a wake-up management circuit 202 and an electronic device 204. As shown in FIG. 2, the wake-up management circuit 202 may be electrically coupled to the electronic device 204. As described above, the wake-up management circuit 202 may facilitate management of power switches associated with the wake-up circuit 202. The wake-up management circuit 202 may be configured to activate substantially all of the power switches, which may be included in the wake-up management circuit, substantially simultaneously. Additionally, the wake-up management circuit 202 may be configured to modulate a level of a control signal of the power switches, which may facilitate to help to flatten a current draw during power-up the electronic device 204. As a result, flattening of a current draw may be facilitated by controlling a current flux in accordance with various embodiments.

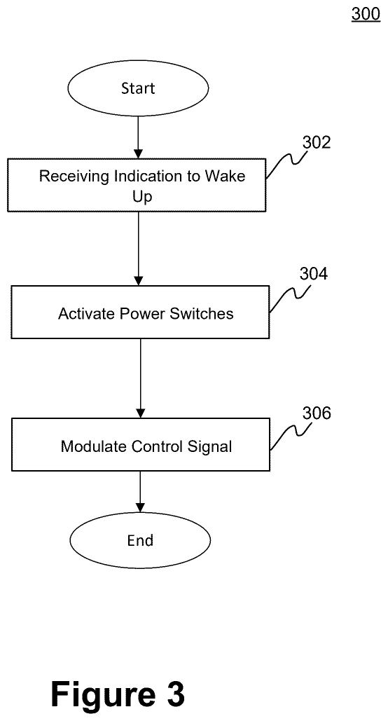

FIG. 3 illustrates an operation flow of the various embodiments disclosed herein. FIG. 3 illustrates an operational flow for facilitating management of a wake-up circuit in accordance with various embodiments. In some portions of the description, illustrative implementations of the method are described with reference to the elements depicted in FIGS. 1-2 and 4-7. However, the described embodiments are not limited to these depictions.

Additionally, FIG. 3 employs block diagrams to illustrate the example methods detailed therein. These block diagrams may set out various functional blocks or actions that may be described as processing steps, functional operations, events and/or acts, etc., and may be performed by hardware, software, and/or firmware. Numerous alternatives to the functional blocks detailed may be practiced in various implementations. For example, intervening actions not shown in the figures and/or additional actions not shown in the figures may be employed and/or some of the actions shown in one figure may be operated using techniques discussed with respect to another figure. Additionally, in some examples, the actions shown in these figures may be operated using parallel processing techniques. The above described, and others not described, rearrangements, substitutions, changes, modifications, etc., may be made without departing from the scope of the claimed subject matter.

In some examples, operational flow 300 may be employed as part of a system for facilitating management of a wake-up circuit as part of an integrated circuit as described herein. Beginning at block 302 (“Receiving Indication to Wake Up”), as part of an integrated circuit, an indication to wake up an electronic device may be received. For example, a wake-up circuit may be configured to receive an indication of some activity and/or activity request for one or more electronic devices included in an electronic device (e.g., memory module).

Continuing from block 302 to block 304 (“Activate Power Switches”), the wake-up circuit may include a number of power switches. The number of power switches may be controlled by a control system such as, but not limited to, a ramp-up control system. The ramp-up control system. The ramp-up control system may be configured as a multi-stage ramp-up control system. The multi-stage ramp-up control system may be configured to activate substantially all of the power switches substantially simultaneously.

Continuing from block 304 to 306 (“Modulate Control Signal”), the control system may be configured to facilitate focusing on modulating a level of a control signal of the power switches. The modulation of the level of the control signal of the power switches may help to flatten a current draw during power-up. In one example, the flattening of the current draw may be facilitated by controlling a current flux. Controlling the current flux may be an alternative to an approach of adding multiple delayed current fluxes.

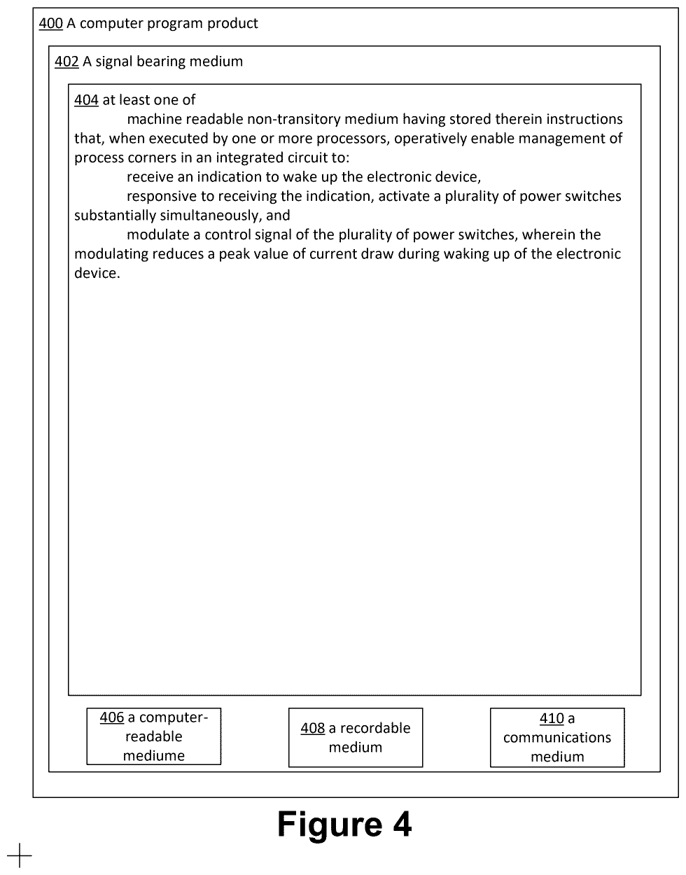

In general, the operational flow described with respect to FIG. 3 and elsewhere herein may be implemented as a computer program product, executable on any suitable computing system, or the like. For example, a computer program product for facilitating passive identification verification and facilitating transactions in a defined area may be provided. Example computer program products may be described with respect to FIG. 4 and elsewhere herein.

FIG. 4 illustrates a computer program product in accordance with various embodiments. FIG. 4 illustrates an example computer program product 400, arranged in accordance with at least some embodiments described herein. Computer program product 400 may include machine readable non-transitory medium having stored therein instructions that, when executed, cause the machine to facilitate management of a wake-up circuit according to the processes and methods discussed herein. Computer program product 400 may include a signal bearing medium 402. Signal bearing medium 402 may include one or more machine-readable instructions 404 which, when executed by one or more processors, may operatively enable a computing device to provide the functionality described herein. In various examples, the devices discussed herein may use some or all of the machine-readable instructions.

In some examples, the machine-readable instructions 404 may include instructions that enable the computing device to receive an indication to wake up the electronic device.

In some examples, the machine-readable instructions 404 may include instructions that enable the computing device to responsive to receiving the indication, activate a plurality of power switches substantially simultaneously.

In some examples, the machine-readable instructions 404 may include instructions that enable the computing device to modulate a control signal of the plurality of power switches, wherein the modulating reduces a peak value of current draw during waking up of the electronic device.

In some implementations, signal bearing medium 402 may encompass a computer-readable medium 406, such as, but not limited to, a hard disk drive, a Compact Disc (CD), a Digital Versatile Disk (DVD), a Universal Serial Bus (USB) drive, a digital tape, memory, etc. In some implementations, the signal bearing medium 402 may encompass a recordable medium 408, such as, but not limited to, memory, read/write (R/W) CDs, R/W DVDs, etc. In some implementations, the signal bearing medium 402 may encompass a communications medium 410, such as, but not limited to, a digital and/or an analog communication medium (e.g., a fiber optic cable, a waveguide, a wired communication link, a wireless communication link, etc.). In some examples, the signal bearing medium 402 may encompass a machine readable non-transitory medium.

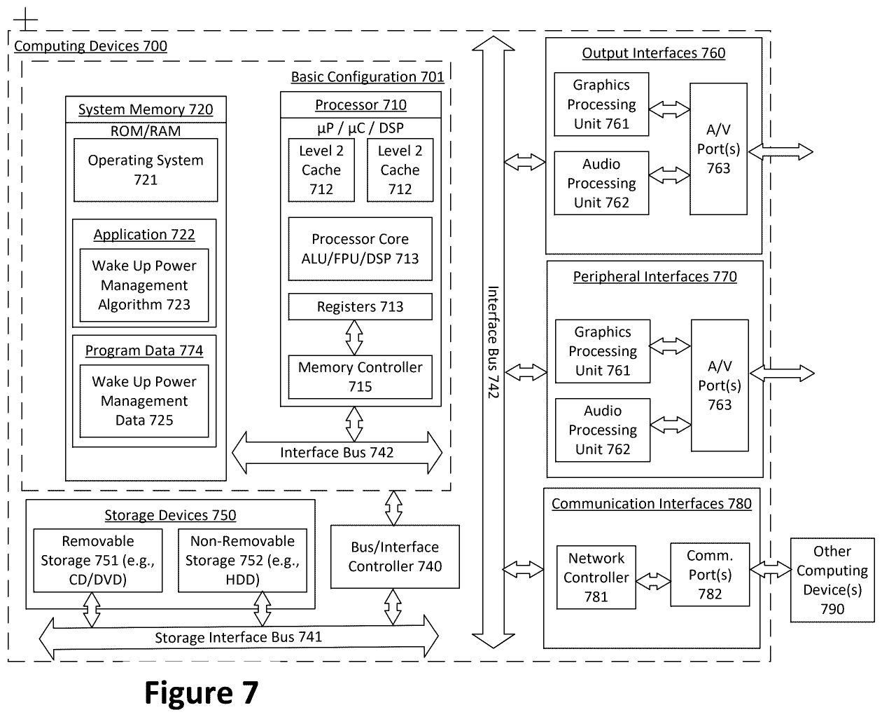

In general, the methods described with respect to FIG. 4 and elsewhere herein may be implemented in any suitable computing system. Example systems may be described with respect to FIG. 7 and elsewhere herein. In general, the system may be configured to facilitate management of wake-up circuits in accordance with various embodiments.

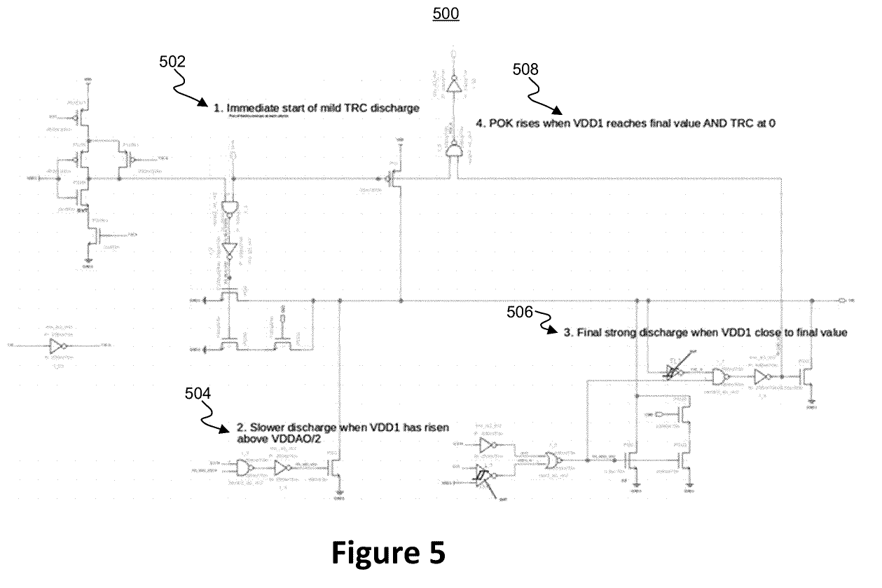

FIG. 5 illustrates examples of some components as to described with respect to various embodiments. In FIG. 1, a circuit schematic may be shown having various electrical components in accordance with at least one embodiment. As shown in FIG. 5, a circuit schematic 500 may include a number of transistors and logic circuits. The number of transistors may include a number of metal oxide semiconductor (MOS) transistors. The MOS transistors may include NMOS and PMOS type transistors. Additionally, the circuit schematic 500 may include logic circuits such as, but not limited to, inverters (not gates) and NAND gates.

Shown in FIG. 5, the circuit schematic 500 may include a number of circuits configured to facilitate “immediate start of mild TRC discharge” (a first circuit schematic area 502). In the first circuit schematic area 502, a number of circuit components may be configured to facilitate discharge of energy that may be stored in a timing resistor and capacitor (TRC) circuit. For example, the TRC circuit may be charged, where the capacitor may accumulate an electrical charge, which may be discharged by providing a discharge path for the capacitor's charge to flow. Accordingly, the mild TRC discharge of the first circuit schematic area 502 may refer to the intentional dissipation of energy stored in a timing resistor and capacitor circuit, which may be part of controlling the timing behavior of the circuit schematic 500 in accordance with various embodiments.

As shown in FIG. 5, the circuit schematic 500 may include a number of circuits configured to facilitate “slower discharge when VDD1 has risen above VDDAO/2” (a second circuit schematic area 504). In the second circuit schematic area 504, a number of circuit components may be configured to facilitate a slower discharge when a supply voltage or power supply voltage (VDD1) has risen above a supply voltage or power supply voltage configured for analog outputs (VDDAO). In this example embodiments, when the VDD1 has risen above VDDAO divided by 2. Some ranges for VDD1 may range from a few volts (e.g., 3.3 V or 5 V) to lower voltages (e.g., 1.8 V or 1.2 V), but are not limited to these ranges based, at least in part, on applications, environments, and/or various design considerations. Some ranges for VDDAO may also range from a few volts (e.g., 3.3 V or 5 V) to lower voltages (e.g., 1.8 V or 1.2 V), but are not limited to these ranges based, at least in part, on applications, environments, and/or various design considerations.

As may be appreciated, since the circuit schematic 500 may be part of or included in a larger electronic component, there may be numerous digital and/or analog devices, which may be communicatively coupled with the circuit schematic 500.

Continuing with description of FIG. 5, in FIG. 5, the circuit schematic 500 may include a number of circuits configured to facilitate “final strong discharge when VDD1 close to final value” (a third circuit schematic area 506).

The circuit schematic 500 may include a number of circuits configured to facilitate “POK rises when VDD1 reaches final value and TRC at 0” (a fourth circuit schematic area 508). In the fourth circuit schematic area 508, the number of circuits may be configured to facilitate a Power-On Reset (POR) signal rising when the VDD1 reaches a final value and the TRC circuit is discharged to 0.

As a result, the circuit schematic 500 shown in FIG. 5 including at least the first, second, third, and fourth circuit schematic areas 502, 504, 506, and 508 may facilitate to activate a number of power switches substantially simultaneously. Additionally, the circuit schematic 500 may facilitate a modulation of a control signal of the number of power switches, where the modulating may help to facilitate reduction in a peak value of current draw during waking up of an electronic device in accordance with various embodiments.

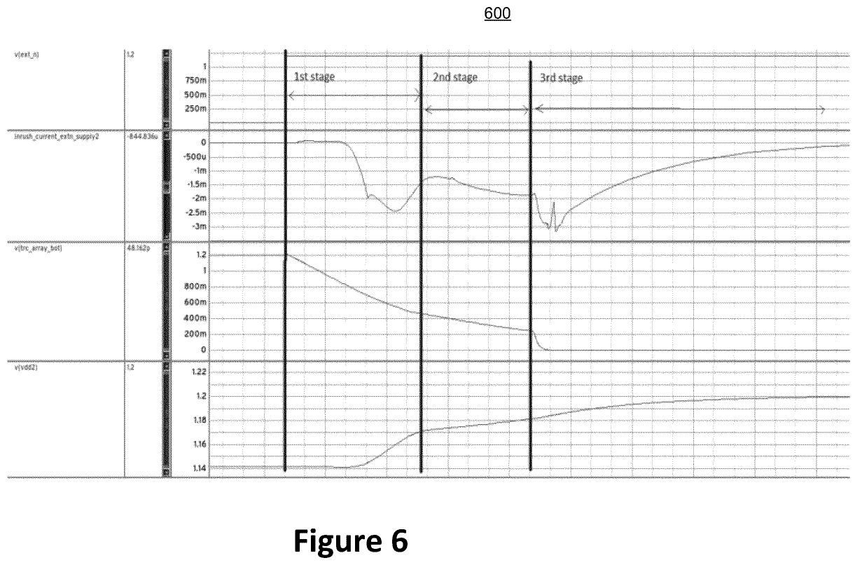

FIG. 6 illustrates examples of some output corresponding to various embodiments. In FIG. 6, an output graph 600 shows a graphical output of a current draw of various embodiments of wake-up circuits and their functionality as described herein.

FIG. 7 illustrates an example computer device. FIG. 7 is a block diagram illustrating an example computing device 700, such as might be embodied by a person skilled in the art, which is arranged in accordance with at least some embodiments of the present disclosure. In one example configuration, computing device 700 may include one or more processors 710 and system memory 720. A memory bus 730 may be used for communicating between the processor 710 and the system memory 720.

Depending on the desired configuration, processor 710 may be of any type including but not limited to a microprocessor (μP), a microcontroller (μC), a digital signal processor (DSP), or any combination thereof. Processor 710 may include one or more levels of caching, such as a level one cache 711 and a level two cache 712, a processor core 713, and registers 714. The processor core 713 may include an arithmetic logic unit (ALU), a floating-point unit (FPU), a digital signal processing core (DSP Core), or any combination thereof. A memory controller 715 may also be used with the processor 710, or in some implementations the memory controller 715 may be an internal part of the processor 710.

Depending on the desired configuration, the system memory 720 may be of any type including but not limited to volatile memory (such as RAM), non-volatile memory (such as ROM, flash memory, etc.) or any combination thereof. System memory 720 may include an operating system 721, one or more applications 722, and program data 724. Application 722 may include wake up power management algorithm 723 that is arranged to perform the functions as described herein including the functional blocks and/or actions described. Program Data 724 may include, among other information described, wake up power management data 725 for use with the process wake up power management algorithm 723. In some example embodiments, application 722 may be arranged to operate with program data 724 on an operating system 721 such that implementations of the management of a wake-up circuit as part of an integrated circuit may be provided as described herein. For example, apparatus described in the present disclosure may comprise all or a portion of computing device 700 and be capable of performing all or a portion of application 722 such that facilitating management of a process corner in an integrated circuit as described herein. This described basic configuration is illustrated in FIG. 7 by those components within dashed line 701.

Computing device 700 may have additional features or functionality, and additional interfaces to facilitate communications between the basic configuration 701 and any required devices and interfaces. For example, a bus/interface controller 740 may be used to facilitate communications between the basic configuration 701 and one or more data storage devices 750 via a storage interface bus 741. The data storage devices 750 may be removable storage devices 751, non-removable storage devices 752, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 720, removable storage 751 and non-removable storage 752 are all examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information, and which may be accessed by computing device 700. Any such computer storage media may be part of device 700.

Computing device 700 may also include an interface bus 742 for facilitating communication from various interface devices (e.g., output interfaces, peripheral interfaces, and communication interfaces) to the basic configuration 701 via the bus/interface controller 740. Example output interfaces 760 may include a graphics processing unit 761 and an audio processing unit 762, which may be configured to communicate to various external devices such as a display or speakers via one or more A/V ports 763. Example peripheral interfaces 760 may include a serial interface controller 771 or a parallel interface controller 772, which may be configured to communicate with external devices such as input devices (e.g., keyboard, mouse, pen, voice input device, touch input device, etc.) or other peripheral devices (e.g., printer, scanner, etc.) via one or more I/O ports 773. An example communication interface 780 includes a network controller 781, which may be arranged to facilitate communications with one or more other computing devices 790 over a network communication via one or more communication ports 782. A communication connection is one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), infrared (IR) and other wireless media. The term computer readable media as used herein may include both storage media and communication media.

Computing device 700 may be implemented as a portion of a small-form factor portable (or mobile) electronic device such as a cell phone, a personal data assistant (PDA), a personal media player device, a wireless web-watch device, a personal headset device, an application specific device, or a hybrid device that includes any of the above functions. Computing device 700 may also be implemented as a personal computer including both laptop computer and non-laptop computer configurations. In addition, computing device 700 may be implemented as part of a wireless base station or other wireless system or device.

It should be appreciated after review of this disclosure that it is contemplated within the scope and spirit of the present disclosure that the claimed subject matter may include a wide variety of integrated circuit devices. Accordingly, the claimed subject matter is not limited in these respects.

Some portions of the foregoing detailed description are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is here, and generally, considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussion utilizing terms such as “processing,” “computing,” “calculating,” “determining” or the like refer to actions or processes of a computing device that manipulates or transforms data represented as physical electronic or magnetic quantities within memories, registers, or other information storage devices, transmission devices, or display devices of the computing device.

Claimed subject matter is not limited in scope to the particular implementations described herein. For example, some implementations may be in hardware, such as those employed to operate on a device or combination of devices, for example, whereas other implementations may be in software and/or firmware. Likewise, although claimed subject matter is not limited in scope in this respect, some implementations may include one or more articles, such as a signal bearing medium, a storage medium and/or storage media. This storage media, such as CD-ROMs, computer disks, flash memory, or the like, for example, may have instructions stored thereon that, when executed by a computing device such as a computing system, computing platform, or other system, for example, may result in execution of a processor in accordance with claimed subject matter, such as one of the implementations previously described, for example. As one possibility, a computing device may include one or more processing units or processors, one or more input/output devices, such as a display, a keyboard and/or a mouse, and one or more memories, such as static random-access memory, dynamic random-access memory, flash memory, and/or a hard drive.

There is little distinction left between hardware and software implementations of aspects of systems; the use of hardware or software is generally (but not always, in that in certain contexts the choice between hardware and software can become significant) a design choice representing cost vs. efficiency tradeoffs. There are various vehicles by which processes and/or systems and/or other technologies described herein can be affected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skilled in the art in light of this disclosure. In addition, those skilled in the art will appreciate that the mechanisms of the subject matter described herein are capable of being distributed as a product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a flexible disk, a hard disk drive (HDD), a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a semiconductor integrated circuit system via a reasonable amount of experimentation. Those having skill in the art will recognize that a typical semiconductor integrated circuit system generally may be included in one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical semiconductor integrated circuit system may be implemented utilizing any suitable commercially available components, such as those typically found in computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Reference in the specification to “an implementation,” “one implementation,” “some implementations,” or “other implementations” may mean that a particular feature, structure, or characteristic described in connection with one or more implementations may be included in at least some implementations, but not necessarily in all implementations. The various appearances of “an implementation,” “one implementation,” or “some implementations” in the preceding description are not necessarily all referring to the same implementations.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter is not limited to the particular examples disclosed, but that such claimed subject matter also may include all implementations falling within the scope of the appended claims, and equivalents thereof.

1. An integrated circuit system for management of wake-up process comprising:
a plurality of electronic devices; and
a wake-up management circuit, the wake-up management circuit electrically coupled with the plurality of electronic devices, the wake-up management circuit configured to wake up at least one of the plurality of electronic devices in multi-stages.

2. The integrated circuit system of claim 1, wherein the plurality of electronic devices comprises a plurality of memory devices.

3. The integrated circuit system of claim 2, wherein the plurality of memory devices comprises at least one of static random-access memory (SRAM), dynamic random-access memory (DRAM), phase change memory (PCM), or resistive random-access memory (RRAM).

4. The integrated circuit system of claim 1, wherein the wake-up circuit comprises a timing resistor capacitor (TRC) circuit.

5. The integrated circuit system of claim 1, wherein the wake-up circuit comprises a plurality of power switches.

6. The integrated circuit system of 5 further comprising a control system.

7. The integrated circuit system of claim 6, wherein the control system comprises a ramp-up control system.

8. The integrated circuit system of claim 1, wherein the wake-up circuit comprises the wake-up circuit configured to slowly discharge responsive to a supply voltage rising above an analog output signal.

9. The integrated circuit system of claim 1, wherein the wake-up circuit comprises the wake-up circuit configured to strongly discharge responsive to a supply voltage being close to a final value.

10. The integrated circuit system of claim 1, wherein the wake-up circuit comprises the wake-up circuit configured to have a power-on reset (POR) signal rise from a low voltage to a high voltage level.

11. The integrated circuit system of claim 1, wherein the wake-up circuit comprises a plurality of metal-oxide semiconductor (MOS) transistors.

12. The integrated circuit system of claim 11, wherein the plurality of MOS transistors comprises a plurality of positive-MOS (pMOS) transistors.

13. The integrated circuit system of claim 8, wherein the plurality of MOS transistors comprises a plurality of negative-MOS (nMOS) transistors.

14. The integrated circuit system of claim 1, wherein the wake-up circuit comprises a plurality of inverters.

15. The integrated circuit system of claim 1, wherein the wake-up circuit comprises a plurality of power switches.

16. A method of managing a wake-up circuit for waking up an electronic device, the method comprising:
receiving an indication to wake up the electronic device;
responsive to receiving the indication, activating a plurality of power switches substantially simultaneously; and
modulating a control signal of the plurality of power switches, wherein the modulating reduces a peak value of current draw during waking up of the electronic device.

17. The method of claim 16, wherein receiving the indication comprises receiving an indication to power up a memory device.

18. The method of claim 16, wherein activating the plurality of power switches comprises activating the plurality of power switches using a ramp-up control system.
